(19) United States
(12) Patent Application Publication
(10) Pub. No.: US 2020/0411346 A1
(43) Pub. Date: Dec. 31, 2020

(54) MANUFACTURING APPARATUS FOR SEMICONDUCTOR DEVICE

(71) Applicant: SAMSUNG ELECTRONICS CO., LTD., Suwon-si (KR)

(72) Inventors: Kyoung Whan OH, Hwaseong-si (KR); Kyung-Won KANG, Yongin-si (KR); Hyeon Jun KANG, Daejeon (KR); Ju Bong LEE, Suwon-si (KR); Sung Hun JANG, Suwon-si (KR); Seok HEO, Hwaseong-si (KR); Hyun Woong HWANG, Suwon-si (KR)

(21) Appl. No.: 16/727,544

(22) Filed: Dec. 26, 2019

(30) Foreign Application Priority Data
Jun. 28, 2019 (KR) 10-2019-0077677

(51) Int. Cl. H01L 21/67; B05C 5/02; B05C 13/02; B05C 11/08

(52) U.S. Cl. CPC H01L 21/67259; B05C 11/08; B05C 13/02; B05C 5/02

(57) ABSTRACT

A manufacturing apparatus for a semiconductor device, the manufacturing apparatus including a spin chuck configured to fix and rotate a wafer; a nozzle configured to spray a chemical toward the wafer; a lateral displacement sensor configured to measure a displacement variation to a lateral surface of the wafer while the spin chuck is being rotated; and a controller configured to control a position of the nozzle by using the displacement variation while the spin chuck is being rotated.

### CROSS-REFERENCE TO RELATED APPLICATION

Korean Patent Application No. 10-2019-0077677, filed on Jun. 28, 2019, in the Korean Intellectual Property Office, and entitled: “Manufacturing Equipment for Semiconductor Device,” is incorporated by reference herein in its entirety.

### BACKGROUND

### 1. Field

Embodiments relate to a manufacturing apparatus for a semiconductor device.

### 2. Description of the Related Art

In a manufacturing process of a semiconductor device, a spin coating device may be used to form a coating film such as photoresist or a planarization film on a wafer. The spin coating device may mount and fix a wafer on a spin chuck, and then uniformly coat a coating film on the surface of the wafer by rotating the wafer at high speed.

### SUMMARY

The embodiments may be realized by providing a manufacturing apparatus for a semiconductor device, the manufacturing apparatus including a spin chuck configured to fix and rotate a wafer; a nozzle configured to spray a chemical toward the wafer; a lateral displacement sensor configured to measure a displacement variation to a lateral surface of the wafer while the spin chuck is being rotated; and a controller configured to control a position of the nozzle by using the displacement variation while the spin chuck is being rotated.

The embodiments may be realized by providing a manufacturing apparatus for a semiconductor device, the manufacturing apparatus including a spin chuck configured to fix and rotate a wafer; a nozzle configured to spray a chemical toward the wafer; a robot arm configured to fix the nozzle and to be driven in a horizontal direction and a vertical direction with respect to a top surface of the wafer; and a lateral displacement sensor configured to measure a displacement variation to a lateral surface of the wafer and a height variation of the lateral surface of the wafer while the spin chuck is being rotated, wherein the robot arm is configured to control a position of the nozzle to correspond to the displacement variation and the height variation, which are measured by the lateral displacement sensor.

The embodiments may be realized by providing a manufacturing apparatus for a semiconductor device, the manufacturing apparatus including a spin chuck configured to fix and rotate a wafer having a photoresist thereon; a nozzle configured to spray a rinse liquid toward the photoresist on an edge of the wafer; a robot arm configured to fix the nozzle and to be driven in a horizontal direction with respect to a top surface of the wafer; and a lateral displacement sensor configured to measure a displacement variation to a lateral surface of the wafer while the spin chuck is being rotated, wherein the robot arm is configured to control a position of the nozzle to correspond to the displacement variation which is measured by the lateral displacement sensor.

### BRIEF DESCRIPTION OF THE DRAWINGS

Features will be apparent to those of skill in the art by describing in detail exemplary embodiments with reference to the attached drawings in which:

FIG. 1 illustrates a schematic configuration diagram of a manufacturing apparatus for a semiconductor device according to some exemplary embodiments.

FIGS. 2 and 3 illustrate schematic views of a lateral displacement sensor of FIG. 1.

FIG. 4 illustrates an exemplary graph of a variation of a displacement of a lateral surface of a wafer with respect to time when the wafer is rotated.

FIGS. 5 and 6 illustrate schematic views of a position movement of a nozzle of FIG. 1.

FIG. 7 illustrates an exemplary graph of a variation of a position of the nozzle with respect to time when the wafer is rotated.

FIGS. 8 and 9 illustrate schematic views of a manufacturing apparatus for a semiconductor device including a magnetic levitation spindle motor according to some exemplary embodiments.

FIGS. 10 to 16 illustrate schematic views of a manufacturing apparatus for a semiconductor device including a two-dimensional displacement sensor according to some exemplary embodiments.

FIG. 17 illustrates graphs representing the manufacturing apparatus learning a displacement variation with respect to time according to some exemplary embodiments.

FIGS. 18 and 19 illustrate schematic views of a manufacturing apparatus for a semiconductor device according to some exemplary embodiments.

FIGS. 20 and 21 illustrate schematic views of a manufacturing apparatus for a semiconductor device according to some exemplary embodiments.

FIGS. 22 and 23 illustrate schematic views of a manufacturing apparatus for a semiconductor device according to some exemplary embodiments.

### DETAILED DESCRIPTION

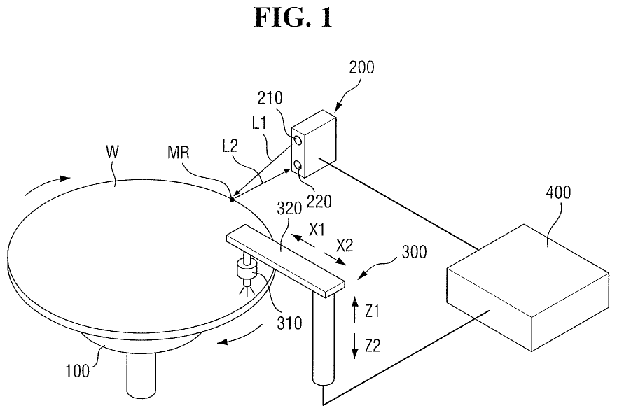

Hereinafter, a manufacturing apparatus for a semiconductor device according to some exemplary embodiments will be described with reference to FIGS. 1 to 23.

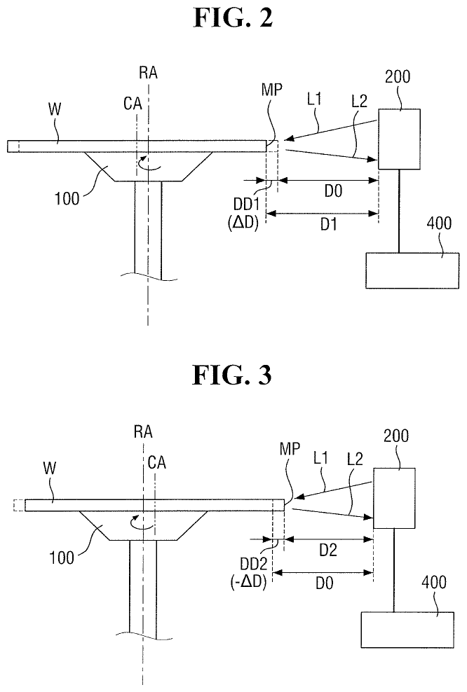

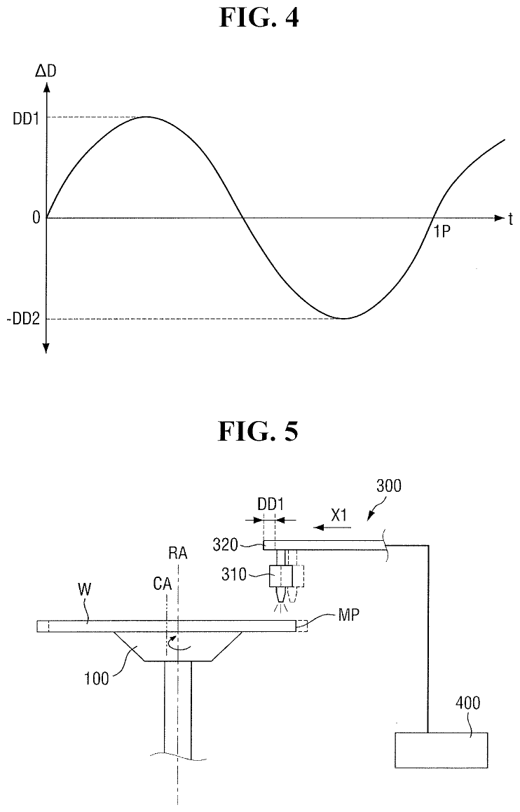

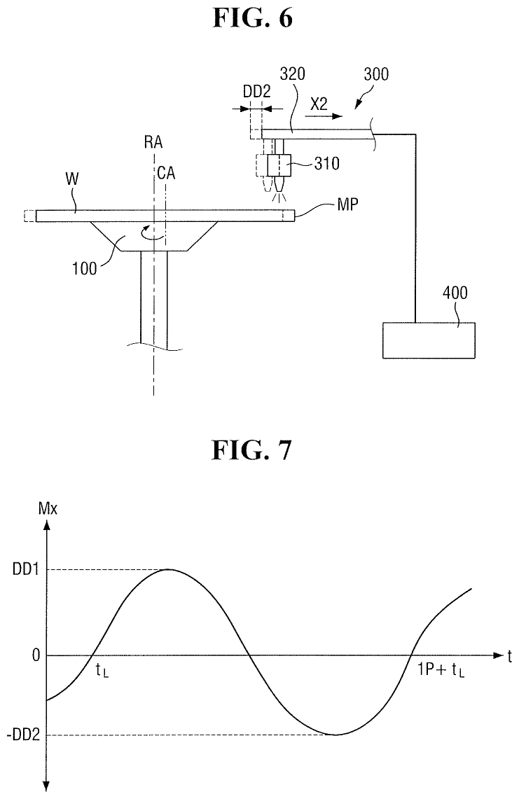

FIG. 1 illustrates a schematic configuration diagram of a manufacturing equipment or apparatus for a semiconductor device according to some exemplary embodiments. FIGS. 2 and 3 illustrate schematic views of a lateral displacement sensor of FIG. 1. FIG. 4 illustrates an exemplary graph of a variation of a displacement of a lateral surface of a wafer with respect to time when the wafer is rotated. FIGS. 5 and 6 illustrate schematic views of a position movement of a nozzle of FIG. 1. FIG. 7 illustrates an exemplary graph of a variation of a position of the nozzle with respect to time when the wafer is rotated.

Referring to FIG. 1, the manufacturing apparatus for the semiconductor device according to some exemplary embodiments may include a spin chuck 100, a lateral displacement sensor 200, a sprayer 300, and a controller 400.

A wafer W may be provided on (e.g., may be accommodated on or by) the spin chuck 100. The spin chuck 100 may fix and rotate the provided wafer W. For example, the spin chuck 100 may fix the wafer W by using vacuum pressure or electrostatic force, and may rotate the fixed wafer W at predetermined RPM.

In an implementation, the spin chuck 100 may rotate the wafer W at high speed. For example, the spin chuck 100 may rotate the wafer W at hundreds to thousands of RPM or higher.

The sprayer 300 may be driven to spray chemical onto the wafer W. For example, the sprayer 300 may include a nozzle 310 and a robot arm 320.

The nozzle 310 may spray a chemical onto the wafer W (that is fixed on the spin chuck 100). The chemical may include materials used for manufacturing a semiconductor device. In an implementation, the chemical may include, e.g., a photoresist composition (for forming a photoresist), a rinse liquid for removing the photoresist or the photoresist composition, a planarization material, or the like.

In an implementation, the nozzle 310 may spray chemical onto the top surface of the wafer W. In an implementation, the nozzle 310 may spray the chemical not only onto the top surface of the wafer W, but also onto a bottom surface of the wafer W. In an implementation, the nozzle 310 may spray the chemical only onto the bottom surface of the wafer W.

The robot arm 320 may move a position of the nozzle 310. For example, the nozzle 310 may be fixed to one end of the robot arm 320. The robot arm 320 may be driven to move the position of the fixed nozzle 310.

In an implementation, the robot arm 320 may be driven in a horizontal direction X1, X2, and/or a vertical direction Z1, Z2 to move the position of the nozzle 310. Herein, the horizontal direction X1, X2 refers to a direction which is horizontal with respect to the top surface of the wafer W, and the vertical direction Z1, Z2 refers to a direction which intersects with the top surface of the wafer W.

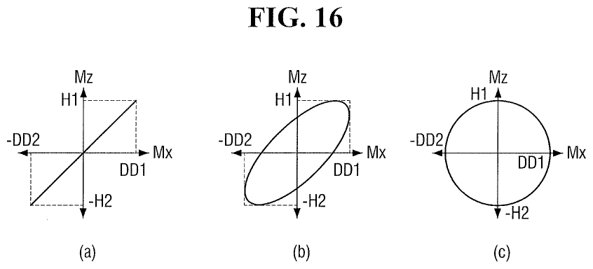

In an implementation, the sprayer 300 may include a piezo actuator. The piezo actuator is an actuator using converse piezoelectric effect, and may precisely control a small displacement at high speed by applying an electric field. For example, the sprayer 300 including the piezo actuator may precisely control the nozzle 310 at high speed to draw a Lissajous curve. The nozzle 310 drawing the Lissajous curve will be described in more detail below with the explanation of FIG. 16.

The lateral displacement sensor 200 may be above a lateral surface of the wafer W. For example, the lateral displacement sensor 200 may be spaced apart from the lateral surface of the wafer W by a predetermined distance. In an implementation, the lateral displacement sensor 200 may measure a displacement to the lateral surface of the wafer W.

In an implementation, the lateral displacement sensor 200 may measure the displacement to the lateral surface of the wafer W by projecting light toward the lateral surface of the wafer W. In an implementation, the lateral displacement sensor 200 may include a laser displacement sensor. For example, the lateral displacement sensor 200 may include a light projector 210 and a light receiver 220.

The light projector 210 may project transmitted light L1 toward a predetermined measurement region MP which is a part of the lateral surface of the wafer W. The light projector 210 may include, e.g., a light emitting element to generate the transmitted light L1, and a control circuit to control the light emitting element. In an implementation, the light emitting element may include, e.g., a laser diode.

The light receiver 220 may receive reflected light L2 that is reflected from the measurement region MP. The light receiver 220 may include, e.g., a light receiving element to receive the reflected light L2, and a circuit to control the light receiving element. In an implementation, the light receiving element may include, e.g., a position sensitive device (PSD), a charged coupled device (CCD), a complementary metal oxide semiconductor (CMOS).

For example, the lateral displacement sensor 200 may measure a displacement from the lateral displacement sensor 200 to the measurement region MP. In an implementation, the lateral displacement sensor 200 may measure the displacement to the lateral surface of the wafer W by using various methods, e.g., a triangular principle method using triangulation, a time of flight (TOF) method using a time spent from light projection to light reception, a phase difference measurement method using a phase difference between transmitted light L1 and reflected light L2, a PN code type measurement method for measuring by using a result of calculating a correlation between transmitted light L1 conducting intensity modulation by a PN code, and reflected light L2 resulting therefrom.

In an implementation, the light projector 210 and the light receiver 220 may be arranged in the vertical direction (e.g., relative to one another) perpendicular to the top surface of the wafer W. In an implementation, the light projector 210 and the light receiver 220 may be arranged in the horizontal direction parallel to the top surface of the wafer W, or may be arranged in different directions.

The controller 400 may be connected with the sprayer 300 and the lateral displacement sensor 200. The controller 400 may control the position of the nozzle 310 of the sprayer 300 by using or based on the displacement measured from the lateral displacement sensor 200 while the wafer W is being rotated. This will be described in more detail below with the explanation of FIGS. 2 to 7.

In an implementation, the controller 400 may include, e.g., a personal computer (PC), a desktop computer, a lap-top computer, a computer workstation, a tablet PC, a server, a mobile computing device, or a combination thereof. In an implementation, the mobile computing device may be implemented by using, e.g., a mobile phone, a smart phone, an enterprise digital assistant (EDA), a digital still camera, a digital video camera, a portable multimedia player (PMP), a personal navigation device or a portable navigation device (PND), a mobile Internet device (MID), a wearable computer, an Internet of things (JOT) device, an Internet of everything (JOE) device, or an e-book.

Referring to FIGS. 2 to 4, the lateral displacement sensor 200 may measure a displacement variation ΔD to the lateral surface of the wafer W while the wafer W is being rotated by the spin chuck 100.

For convenience of explanation, FIG. 2 illustrates a visual point from which the displacement between the lateral displacement sensor 200 and the lateral surface of the wafer W is greatest, and FIG. 3 illustrates a visual point from which the displacement between the lateral displacement sensor 200 and the lateral surface of the wafer W is smallest. For reference, D0 in FIGS. 2 and 3 refers to a displacement between the lateral displacement sensor 200 and the lateral surface of the wafer W when a rotation axis RA of the wafer W and a center axis CA of the wafer W coincide with each other.

For example, when the wafer W is rotated by the spin chuck 100, the rotation axis RA of the wafer W and the center axis CA of the wafer W may not completely or perfectly coincide with each other. In an implementation, this may be attributable to, e.g., a position change of a wafer carrier, a position change of the spin chuck, a height change of the spin chuck, a slope change of the spin chuck, or the like, which could be caused by operation of the manufacturing apparatus for the semiconductor device.

For example, the displacement between the lateral displacement sensor 200 and the lateral surface of the wafer W may be continuously changed as the wafer W is rotated. For example, when the rotation axis RA of the wafer W and the center axis CA of the wafer W do not completely coincide with each other, the displacement variation ΔD to the lateral surface of the wafer W may be continuously changed while the wafer W is being rotated. Herein, the displacement variation ΔD may be defined as a variation of the displacement between the lateral displacement sensor 200 and the lateral surface of the wafer W with reference to D0.

In an implementation, the center axis CA of the wafer W may be further away from the lateral displacement sensor 200 than the rotation axis RA of the wafer W while the wafer W is being rotated. For example, a displacement D1 between the lateral displacement sensor 200 and the lateral surface of the wafer W may be longer than D0 as shown in FIG. 2. For example, the displacement variation ΔD may have a positive value. For example, in FIG. 2, the displacement variation ΔD may be DD1 which is D1 minus D0.

In an implementation, the center axis CA of the wafer W may be closer to the lateral displacement sensor 200 than the rotation axis RA of the wafer W while the wafer W is being rotated. For example, a displacement D2 between the lateral displacement sensor 200 and the lateral surface of the wafer W may be shorter than D0 as shown in FIG. 3. For example, the displacement variation ΔD may have a negative value. For example, in FIG. 2, the displacement variation ΔD may be −DD2 which is D2 minus D0.

In an implementation, the displacement variation ΔD to the lateral surface of the wafer W may be provided to the controller 400 while the wafer W is being rotated. In an implementation, the displacement variation ΔD may have a certain variation within a range of ±300 μm.

In an implementation, the displacement variation ΔD to the lateral surface of the wafer W may be changed in the pattern of a sine function while the wafer W is being rotated. For example, the displacement variation ΔD may draw a sine curve with respect to time t while the wafer W is being rotated as shown in FIG. 4.

In an implementation, a period 1P of the sine curve of FIG. 4 may be a time during which the wafer W is rotated one time. FIG. 2 illustrates the visual point from which the displacement between the lateral displacement sensor 200 and the lateral surface of the wafer W is greatest, and a maximum value of the sine curve of FIG. 4 may be DD1. FIG. 3 illustrates the visual point from which the displacement between the lateral displacement sensor 200 and the lateral surface of the wafer W is smallest, and a minimum value of the sine curve of FIG. 4 may be −DD2.

Referring to FIGS. 5 and 6, the position of the nozzle 310 may be moved based on the displacement variation ΔD measured by the lateral displacement sensor 200.

In an implementation, the center axis CA of the wafer W may be further away from the nozzle 310 than the rotation axis RA of the wafer W while the wafer W is being rotated. In this case, the robot arm 320 may be driven in the horizontal direction X1 toward the center axis CA of the wafer W as shown in FIG. 5. For example, the nozzle 310 may be moved in the X1 direction and may spray a chemical onto the wafer W.

In an implementation, the center axis CA of the wafer W may be closer to the nozzle 310 than the rotation axis RA of the wafer W while the wafer W is being rotated. In this case, the robot arm 320 may be driven in the horizontal direction X2 away from the center axis CA of the wafer Was shown in FIG. 6. For example, the nozzle 310 may be moved in the X2 direction and may spray a chemical onto the wafer W.

In an implementation, the controller 400 may control the position of the nozzle 310 to correspond to the displacement variation ΔD provided from the lateral displacement sensor 200. For example, the lateral displacement sensor 200 may measure the displacement variation ΔD to the measurement region MP, and may provide the result of measurement to the controller 400. Subsequently, when the measurement region MP is positioned below the nozzle 310, the controller 400 may move the position of the nozzle 310 as much as the displacement variation ΔD of the measurement region MP. For example, when the displacement variation ΔD falls within the range of ±300 μm, an amount of movement of the position of the nozzle 310 may also fall within the range of ±300 μm.

In an implementation, the displacement variation ΔD of the measurement region MP may be DD1 as shown in FIG. 2. In this case, when the measurement region MP is positioned below the nozzle 310, the nozzle 310 may be moved by DD1 in the X1 direction as shown in FIG. 5.

In an implementation, the displacement variation ΔD of the measurement region MP may be −DD2 as shown in FIG. 3. In this case, when the measurement region MP is positioned below the nozzle 310, the nozzle 310 may be moved by DD2 in the X2 direction as shown in FIG. 6.

Accordingly, in the manufacturing apparatus for the semiconductor device according to some exemplary embodiments, the nozzle 310 may spray a chemical onto the wafer W while maintaining a constant distance from the lateral surface of the wafer W, in spite of or independent of the change in the displacement of the lateral surface of the wafer W.

In an implementation, the amount of movement Mx of the position of the nozzle 310 in the horizontal direction may be changed in the pattern of a sine function while the wafer W is being rotated. For example, the displacement variation ΔD may draw the sine curve with respect to time t while the wafer W is being rotated as shown in FIG. 4. In this case, the amount of movement Mx of the position of the nozzle 310 in the horizontal direction may also draw a sine curve with respect to time t while the wafer W is being rotated as shown in FIG. 7.

A period 1P of the sine curve of FIG. 7 may be the same as the period 1P of the sine curve of FIG. 4. For example, the period 1P of the sine curve of FIG. 7 may be a time during which the wafer W is rotated one time. As described above, the position of the nozzle 310 may be moved to correspond to the displacement variation ΔD. For example, a maximum value of the sine curve of FIG. 7 may be DD1, and a minimum value may be −DD2.

In an implementation, the controller 400 may control the position of the nozzle 310 by reflecting a latency time t_{L}. The latency time t_{L} may be a predetermined time that is assigned by the controller 400 to exactly reflect the displacement variation ΔD measured from the lateral displacement sensor 200 at the time when the chemical sprayed from the nozzle 310, moved in position, is coated over the wafer W.

For example, the latency time t_{L} may reflect a time taken for the lateral displacement sensor 200 to measure the displacement to the measurement region MP, a time taken to calculate the displacement variation ΔD on the measurement region MP, a time taken for the measurement region MP to be moved below the nozzle 310, a time taken to drive the robot arm 320, a time taken to spray chemical from the nozzle 310, a time taken to coat the sprayed chemical over the wafer W, or the like.

In an implementation, the position of the nozzle 310 may be moved after the predetermined latency time ti, from the time that the lateral displacement sensor 200 measures the displacement variation ΔD. For example, the sine curve of FIG. 7 may have a shape shifted from the sine curve of FIG. 4 as much as the latency time t_{L} in parallel in the time t-axis direction.

In a manufacturing process of a semiconductor device, manufacturing apparatus for the semiconductor device for coating chemical over a wafer rotating at high speed may be used. However, due to the possibility of a problem in some apparatuses, the chemical may not be exactly or accurately sprayed onto a desired point of the wafer rotating at high speed.

For example, as the manufacturing apparatus for the semiconductor device is run, the wafer may not be exactly fixed to a spin chuck due to a position change of a wafer carrier, a position change of the spin chuck, a height change of the spin chuck, a slope change of the spin chuck, or the like. For example, a rotation axis of the wafer and a center axis of the wafer may not coincide with each other. For example, a position of a nozzle relative to a lateral surface of the wafer may be continuously changed while the wafer is being rotated, and it may be difficult for the nozzle to accurately coat the chemical over a desired point of the wafer.

The manufacturing apparatus for the semiconductor device according to some exemplary embodiments may measure a change in the displacement to the lateral surface of the wafer W by using the lateral displacement sensor 200, and may move the position of the nozzle 310 to reflect the change in the displacement. For example, the manufacturing apparatus for the semiconductor device according to some exemplary embodiments may spray a chemical onto the wafer W while maintaining a constant distance from the lateral surface of the wafer W by calibrating the displacement variation ΔD of the lateral surface of the wafer W. For example, the manufacturing apparatus for the semiconductor device according to some exemplary embodiments may compensate, in real time, for variations in the position of the nozzle 310 relative to a desired spray position on the wafer W, by continually adjusting the position of the nozzle 310 in response to wafer W position data from the lateral displacement sensor 200. For example, the manufacturing apparatus for the semiconductor device according to an embodiment may help reduce prevent a defect of a manufactured semiconductor device by exactly or accurately spraying chemical onto a desired point of the wafer W, in spite of the displacement variation ΔD of the lateral surface of the wafer W.

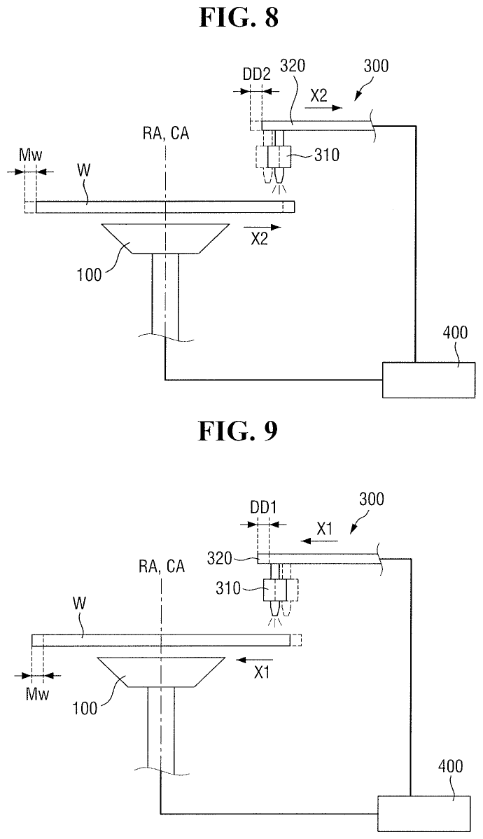

FIGS. 8 and 9 illustrate schematic views of a manufacturing apparatus for a semiconductor device including a magnetic levitation spindle motor according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIGS. 8 and 9, in the manufacturing apparatus for the semiconductor device according to some exemplary embodiments, the spin chuck 100 may include a magnetic levitation spindle motor.

The spin chuck 100 including the magnetic levitation spindle motor may rotate, supporting the wafer W in a contactless manner by using the principle of magnetic levitation. For example, as shown in the drawings, the wafer W may be rotated while being spaced apart from the spin chuck 100.

The spin chuck 100 including the magnetic levitation spindle motor may control a position of the wafer W. In an implementation, the controller 400 may be connected to the spin chuck 100. The controller 400 may control the position of the wafer W by controlling the spin chuck 100 including the magnetic levitation spindle motor.

In an implementation, the controller 400 may make the rotation axis RA of the wafer W and the center axis CA of the wafer W coincide with each other by using the displacement variation ΔD provided from the lateral displacement sensor 200.

For example, as shown in FIG. 2, the rotation axis RA of the wafer W and the center axis CA of the wafer W may not coincide with each other. In this case, the spin chuck 100 may move the wafer W by a distance Mw in the X2 direction as shown in FIG. 8. For example, the rotation axis RA of the wafer W and the center axis CA of the wafer W may coincide with each other.

In an implementation, the position of the nozzle 310 may also be moved according to the movement of the wafer W. For example, the robot arm 320 may also be driven in the X2 direction according to the movement of the wafer W in the X2 direction. For example, the position of the nozzle 310 may be moved in the X2 direction. In an implementation, the controller 400 may move the position of the nozzle 310 as much as the amount of movement Mw of the position of the wafer W. For example, a position variation DD2 of the nozzle 310 may be the same as the amount of movement Mw of the position of the wafer W.

In an implementation, the rotation axis RA of the wafer W and the center axis CA of the wafer W may not coincide with each other, as shown in FIG. 3. In this case, the spin chuck 100 may move the wafer W by the distance Mw in the X1 direction as shown in FIG. 9. For example, the rotation axis RA of the wafer W and the center axis CA of the wafer W may coincide with each other.

In an implementation, the position of the nozzle 310 may also be moved according the movement of the wafer W. For example, the robot arm 320 may also be driven in the X1 direction according to the movement of the wafer W in the X1 direction. Accordingly, the position of the nozzle 310 may be moved in the X1 direction. In an implementation, the controller 400 may move the position of the nozzle 310 as much as the amount of movement Mw of the position of the wafer W. For example, a position variation DD1 of the nozzle 310 may be the same as the amount of movement Mw of the position of the wafer W.

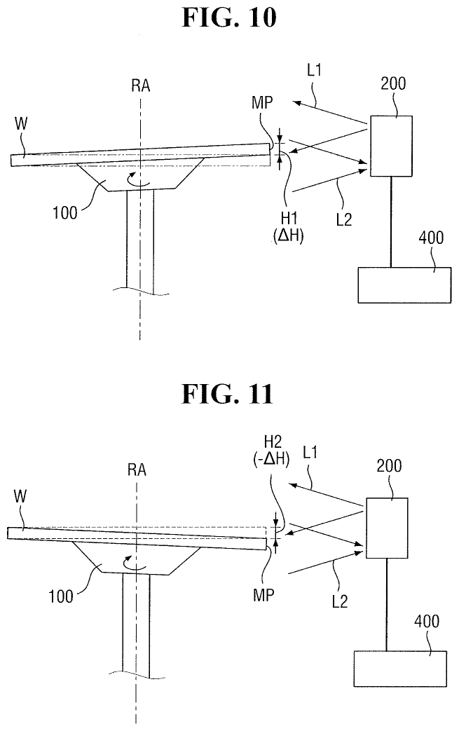

FIGS. 10 to 16 illustrate schematic views of a manufacturing apparatus for a semiconductor device including a multi-dimensional (e.g., two-dimensional) displacement sensor according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIGS. 10 to 16, in the manufacturing apparatus for the semiconductor device according to some exemplary embodiments, the lateral displacement sensor 200 may include a multi-dimensional displacement sensor.

For convenience of explanation, hereinafter, FIG. 10 illustrates a visual point from which a height of the lateral surface of the wafer W on the measurement region MP is highest, and FIG. 11 illustrates a visual point from which the height of the lateral surface of the wafer W on the measurement region MP is lowest. Furthermore, for convenience of explanation, the illustration of a displacement variation (for example, ΔD of FIGS. 2 and 3) to the lateral surface of the wafer W is omitted from FIGS. 10 and 11.

The lateral displacement sensor 200 including the multi-dimensional displacement sensor may project linear transmitted light L1 and may receive linear reflected light L2. In an implementation, as shown in the drawings, the lateral displacement sensor 200 may project transmitted light L1 in the form of a line extending upward and downward, and may receive reflected light L2 resulting therefrom. For example, the lateral displacement sensor 200 may measure not only the displacement variation ΔD to the lateral surface of the wafer W, but also a height variation ΔH of the lateral surface of the wafer W.

In an implementation, the wafer W may be fixed to the spin chuck 100 and rotated while being tilted. In an implementation, when being rotated by the spin chuck 100, the wafer W could be repeatedly tilted by shaking. In an implementation, this may be attributable to, e.g., a position change of a wafer carrier, a position change of the spin chuck, a height change of the spin chuck, a slope change of the spin chuck, or the like, which could caused by operation of the manufacturing apparatus for the semiconductor device.

For example, the height variation ΔH of the lateral surface of the wafer W may be continuously changed while the wafer W is being rotated. Herein, the height variation ΔH may be defined as a variation of the height of the top surface of an edge of the wafer W with reference to a height when the wafer W is not tilted. In an implementation, the height variation ΔH of the wafer W may have a certain variation within a range of, e.g., ±500 μm.

In an implementation, the height of the lateral surface of the wafer W adjacent to the lateral displacement sensor 200 may increase while the wafer W is being rotated. For example, the height of the lateral surface of the wafer W on the measurement region MP may increase by H1 as shown in FIG. 10. For example, the height variation ΔH may have a positive value.

In an implementation, the height of the lateral surface of the wafer W adjacent to the lateral displacement sensor 200 may decrease while the wafer W is being rotated. For example, the height of the lateral surface of the wafer W on the measurement region MP may decrease by H2 as shown in FIG. 11. For example, the height variation ΔH may have a negative value.

In an implementation, the height variation ΔH of the lateral surface of the wafer W may be provided to the controller 400 while the wafer W is being rotated.

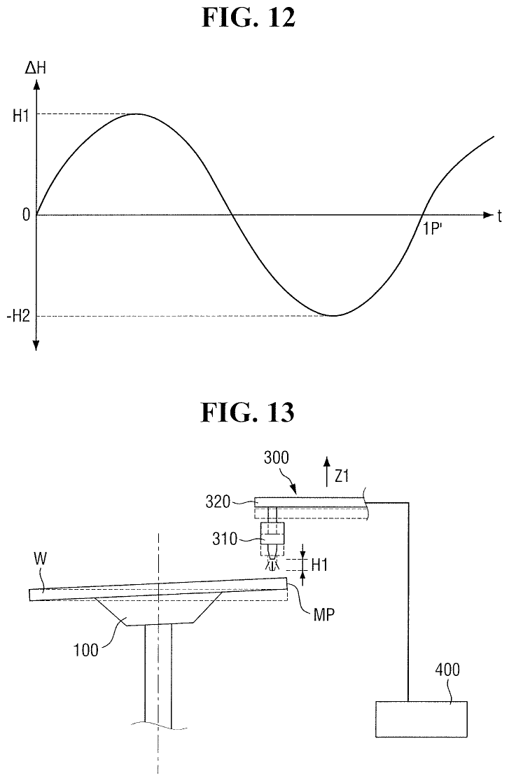

In an implementation, the height variation ΔH of the lateral surface of the wafer W may be changed in the pattern of a sine function while the wafer W is being rotated. For example, the height variation ΔH may draw a sine curve with respect to time t while the wafer W is being rotated, as shown in FIG. 12.

In an implementation, a period 1P′ of the sine curve of FIG. 12 may be the same as the period 1P of the sine curve of FIG. 4. For example, the period 1P′ of the sine curve of FIG. 12 may be a time during which the wafer W is rotated one time. In an implementation, the period 1P′ of the sine curve of FIG. 12 may be different from the period 1P of the sine curve of FIG. 4 according to the manufacturing apparatus for the semiconductor device. For example, the period 1P′ of the sine curve of FIG. 12 may be shorter or longer than the time during which the wafer W is rotated one time.

FIG. 10 illustrates the visual point from which the height of the lateral surface of the wafer W is highest, and a maximum value of the sine curve of FIG. 12 may be H1. FIG. 11 illustrates the visual point from which the height of the lateral surface of the wafer W is lowest, and a minimum value of the sine curve of FIG. 12 may be −H2.

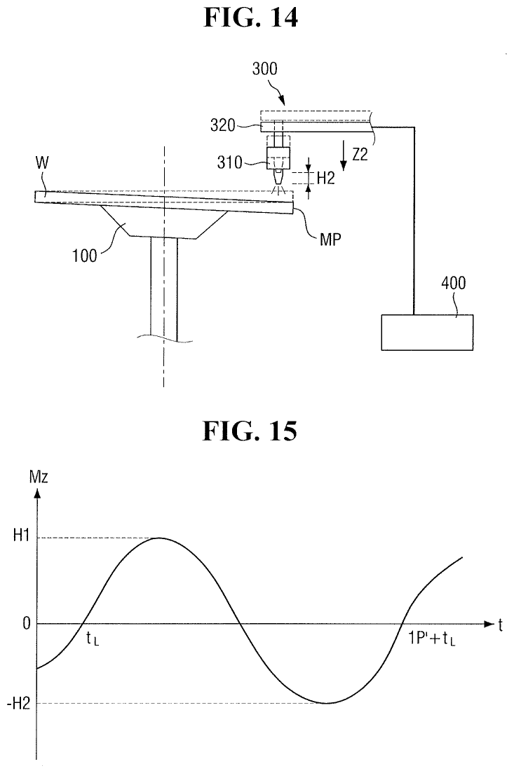

Referring to FIGS. 13 and 14, the position of the nozzle 310 may be moved based on the height variation ΔH measured by the lateral displacement sensor 200.

In an implementation, the height of the lateral surface of the wafer W adjacent to the lateral displacement sensor 200 may increase while the wafer W is being rotated. In this case, the robot arm 320 may be driven in the vertical direction Z1 upwardly as shown in FIG. 13. For example, the nozzle 310 may be moved in the Z1 direction and may still accurately spray the chemical onto the wafer W.

In an implementation, the height of the lateral surface of the wafer W adjacent to the lateral displacement sensor 200 may decrease while the wafer W is being rotated. In this case, the robot arm 320 may be driven in the vertical direction Z2 downwardly as shown in FIG. 14. For example, the nozzle 310 may be moved in the Z2 direction and may still accurately spray the chemical onto the wafer W.

For example, when the height variation ΔH falls within the range of ±500 μm, the amount of movement of the position of the nozzle 310 may also fall within the range of ±500 μm.

In an implementation, in the manufacturing apparatus for the semiconductor device according to some exemplary embodiments, the nozzle 310 may spray the chemical onto the wafer W while maintaining a constant distance to the top surface of the wafer W, in spite of the change in the height of the lateral surface of the wafer W.

In an implementation, the amount of movement Mz of the position of the nozzle 310 in the vertical direction may be changed in the pattern of a sine function. For example, the height variation ΔH may draw a sine curve with respect to time t while the wafer W is being rotated as shown in FIG. 12. For example, the amount of movement Mz of the position of the nozzle 310 in the vertical direction may also draw a sine curve with respect to time t while the wafer W is being rotated as shown in FIG. 15.

A period 1P′ of the sine curve of FIG. 15 may be the same as the period 1P′ of the sine curve of FIG. 12. As described above, the position of the nozzle 310 may be moved to correspond to the height variation ΔH. Accordingly, a maximum value of the sine curve of FIG. 15 may be H1, and a minimum value may be −H2.

In an implementation, the position of the nozzle 310 may be moved after a predetermined latency time t_{L} from the time that the lateral displacement sensor 200 measures the height variation ΔH. For example, the sine curve of FIG. 15 may have a shape shifted from the sine curve of FIG. 12 as much as the latency time t_{L} in parallel in the time t-axis direction.

Referring to FIG. 16, in the manufacturing apparatus for the semiconductor device according to some exemplary embodiments, the nozzle 310 may move, drawing a Lissajous curve.

As described above, the amount of movement Mx of the position of the nozzle 310 in the horizontal direction may be changed in the pattern of a sine function, and the amount of movement Mz of the position of the nozzle 310 in the vertical direction may also be changed in the pattern of a sine function while the wafer W is being rotated. For example, while the wafer W is being rotated, the nozzle 310 may move, drawing the Lissajous curve on a plane including the horizontal direction X1, X2 and the vertical direction Z1, Z2.

Parts (a), (b), and (c) of FIG. 16 respectively illustrate exemplary Lissajous curves drawn by the nozzle 310. For convenience of explanation, parts (a), (b), and (c) of FIG. 16 illustrate only that a period of the amount of movement Mx of the position in the horizontal direction (e.g., 1P of FIG. 7) and a period of the amount of movement Mz of the position in the vertical direction (e.g., 1P′ of FIG. 7) are the same. In an implementation, the period of the amount of movement Mx of the position of the nozzle 310 in the horizontal direction (e.g., 1P of FIG. 7) and the period of the amount of movement Mz of the position of the nozzle 310 in the vertical direction (e.g., 1P′ of FIG. 7) may be different from each other. For example, the nozzle 310 may draw Lissajous curves other than the Lissajous curves shown in FIGS. 16A, 16B, and 16C.

Part (a) of FIG. 16 illustrates a case in which a phase of the amount of movement Mx of the position in the horizontal direction and a phase of the amount of movement Mz of the position in the vertical direction are the same. For example, a point at which the displacement variation ΔD is 0 and a point at which the height variation ΔH is 0 may coincide with each other. In this case, while the wafer W is being rotated, the nozzle 310 may repeat a rectilinear motion in a diagonal direction on the plane including the horizontal direction X1, X2 and the vertical direction Z1, Z2.

Part (b) of FIG. 16 illustrates a case in which the phase of the amount of movement Mx of the position in the horizontal direction and the phase of the amount of movement Mz of the position in the vertical direction are different. For example, when the displacement variation ΔD is 0, the height variation ΔH may not be 0. Alternatively, when the height variation ΔH is 0, the displacement variation ΔD may not be 0. In this case, while the wafer W is being rotated, the nozzle 310 may repeat an elliptic motion on the plane including the horizontal direction X1, X2 and the vertical direction Z1, Z2.

Part (c) of FIG. 16 illustrates a case in which the phase of the amount of movement Mx of the position in the horizontal direction and the phase of the amount of movement Mz of the position in the vertical direction are different by half of the period (1P of FIG. 7 or 1P′ of FIG. 15). In an implementation, when the displacement variation ΔD is 0, the position variation ΔH may be H1 or −H2. In an implementation, when the position variation ΔH is 0, the displacement variation ΔD may be DD1 or −DD2. In this case, while the wafer W is being rotated, the nozzle 310 may repeat a circular motion on the plane including the horizontal direction X1, X2 and the vertical direction Z1, Z2.

In an implementation, the sprayer 300 may include a piezo actuator to control the nozzle 310 drawing a Lissajous curve.

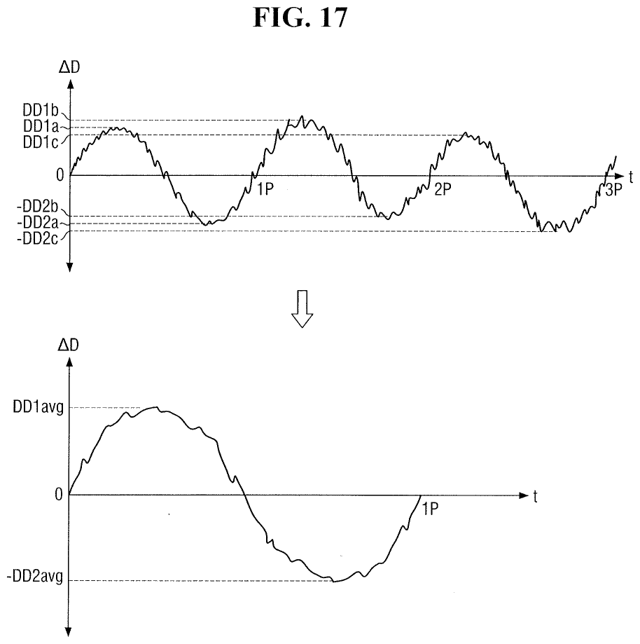

FIG. 17 illustrates graphs representing the manufacturing apparatus learning a displacement variation with respect to time according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIG. 17, the manufacturing apparatus for the semiconductor device according to some exemplary embodiments may learn the displacement variation ΔD and may control the position of the nozzle 310. For convenience of explanation, the displacement variation ΔD will be mainly described hereinbelow. In an implementation, the manufacturing apparatus for the semiconductor device according to some exemplary embodiments may also learn the height variation ΔH.

For example, the controller 400 may learn the displacement variation ΔD with respect to time t while the wafer W is rotated a predetermined number of times. For example, as shown in FIG. 17, the displacement variation ΔD with respect to time t may be learned while the wafer W is rotated three times.

In an implementation, the controller 400 may measure displacement variations ΔD during a plurality of periods (e.g., while the wafer W is rotated a predetermined number of times), may average the displacement variations ΔD regarding the respective periods, and may learn the displacement variation ΔD with respect to time t. For example, the controller 400 may average displacement variations ΔD regarding respective rotation periods.

For example, the displacement variation ΔD with respect to time t measured by the lateral displacement sensor 200 may include a noise. For example, a maximum value of the displacement variation ΔD during a first period (0-1P) may be DD1a, a maximum value of the displacement variation ΔD during a second period (1P-2P) may be DD1b which is different from DD1a, and a maximum value of the displacement variation ΔD during a third period (2P-3P) may be DD1c which is different from DD1a and DD1b. Likewise, for example, a minimum value of the displacement variation ΔD during the first period (0-1P) may be DD2a, a minimum value of the displacement variation ΔD during the second period (1P-2P) may be DD2b which is different from DD2a, and a minimum value of the displacement variation ΔD during the third period (2P-3P) may be DD2c which is different from DD2a and DD2b.

In this case, the controller 400 may provide the learned displacement variation ΔD by averaging the displacement variations ΔD regarding the first period (0-1P), the second period (1P-2P), and the third period (2P-3P). For example, the maximum value of the learned displacement variation ΔD may be an average of DD1a, DD1b, and DD1c. Likewise, for example, the minimum value of the learned displacement variation ΔD may be an average of DD2a, DD2b, and DD2c.

Accordingly, even when the displacement variation ΔD with respect to time t includes a noise, the displacement variation ΔD with an enhanced degree of precision can be provided. For example, a non-repeatable run-out (NRRO) may be reduced and only a repeatable run-out (RRO) may remain by measuring the displacement variations ΔD regarding the plurality of periods. In addition, errors for the respective periods may be offset by one another by averaging the displacement variations ΔD regarding the respective periods. Accordingly, the displacement variation ΔD with a minimized noise can be provided.

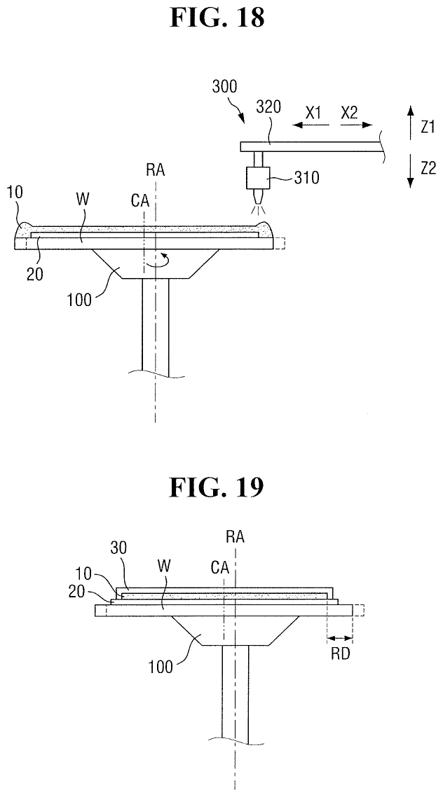

FIGS. 18 and 19 illustrate schematic views of a manufacturing apparatus for a semiconductor device according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIGS. 18 and 19, in the manufacturing apparatus for the semiconductor device according to some exemplary embodiments, the sprayer 300 may remove an edge bead of a first coating film 10.

For example, as shown in FIG. 18, the first coating film 10 may be coated over the wafer W. In an implementation, the first coating film 10 may include, e.g., a photoresist composition.

In an implementation, the robot arm 320 may control the position of the nozzle 310 in order for the nozzle 310 to spray chemical toward an edge of the wafer W. Controlling the position of the nozzle 310 has been described above with reference to FIGS. 1 to 17, and a repeated detailed description thereof may be omitted herein.

Accordingly, as shown in FIG. 19, a chemical sprayed toward the edge of the wafer W from the nozzle 310 may uniformly remove the edge bead of the first coating film 10 coated over the wafer W. In an implementation, the chemical may include, e.g., a rinse liquid to remove a photoresist or the photoresist composition. In an implementation, a depth RD by which the edge bead of the first coating film 10 is removed may be, e.g., about 0.3 mm to about 0.8 mm. In an implementation, the depth RD by which the edge bead of the first coating film 10 is removed may be, e.g., about 1.0 mm to 1.2 mm.

In an implementation, a reflection prevention film 20 may be interposed between the wafer W and the first coating film 10. The reflection prevention film 20 may, e.g., help prevent diffused reflection of light projected onto the wafer W. In an implementation, the reflection prevention film 20 may help enhance hydrophobicity of the first coating film 10. When light projected onto the wafer W is an argon fluoride (ArF) light source, a thickness of the reflection prevention film 20 may be about 20 nm to about 30 nm. When light projected onto the wafer W is an extreme ultraviolet (EUV) light source, a thickness of the reflection prevention film 20 may be about 40 nm to about 50 nm.

In an implementation, the edge bead of the first coating film 10 may be removed, such that an edge of the reflection prevention film 20 is exposed.

In an implementation, after the edge bead of the first coating film 10 is removed, a second coating film 30 may be formed on the first coating film 10. The second coating film 30 may be formed to cover the first coating film 10. The second coating film 30 may, e.g., reinforce the hydrophobicity of the first coating film 10. A thickness of the second coating film 30 may be, e.g., about 80 nm to about 100 nm.

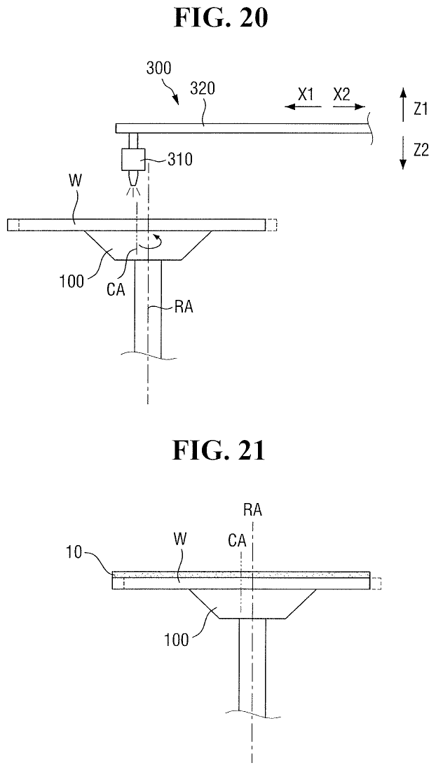

FIGS. 20 and 21 illustrate schematic views of a manufacturing apparatus for a semiconductor device according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIGS. 20 and 21, in the manufacturing apparatus for the semiconductor device according to some exemplary embodiments, the sprayer 300 may coat the first coating film 10 over the wafer W.

In an implementation, the robot arm 320 may control the position of the nozzle 310 in order for the nozzle 310 to spray the chemical toward the center axis CA of the wafer W. Controlling the position of the nozzle 310 has been described above with reference to FIGS. 1 to 17, and thus a detailed description thereof is omitted herein.

Accordingly, as shown in FIG. 21, the chemical sprayed toward the center axis CA of the wafer W from the nozzle 310 may form the uniform first coating film 10 on the wafer W. In an implementation, the chemical may include, e.g., a photoresist composition.

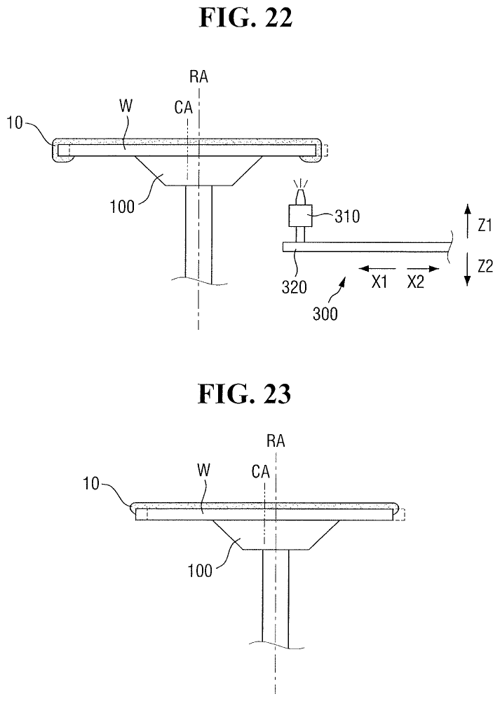

FIGS. 22 and 23 illustrate schematic views of a manufacturing apparatus for a semiconductor device according to some exemplary embodiments. For convenience of explanation, elements or operations overlapping with those described above with reference to FIGS. 1 to 7 will not be described or described as briefly as possible for the sake of brevity.

Referring to FIGS. 1 to 7 and FIGS. 22 and 23, in the manufacturing apparatus for the semiconductor device according to some exemplary embodiments, the sprayer 300 may remove the first coating film 10 coated over a rear surface of the wafer W.

For example, as shown in FIG. 22, the first coating film 10 may be coated over the rear surface of the wafer W. In an implementation, the first coating film 10 may include, e.g., a photoresist composition.

In an implementation, the robot arm 320 may control the position of the nozzle 310 in order for the nozzle 310 to spray the chemical toward an edge of the rear surface of the wafer W. Controlling the position of the nozzle 310 has been described above with reference to FIGS. 1 to 17, and a repeated detailed description thereof is omitted herein.

For example, as shown in FIG. 23, the chemical sprayed toward the edge of the wafer W from the nozzle 310 may uniformly remove the first coating film 10 coated over the rear surface of the wafer W. In addition, the chemical sprayed toward the edge of the wafer W from the nozzle 310 may precisely control a limit to removing the first coating film 10. In an implementation, the chemical may include, e.g., a rinse liquid to remove the photoresist or the photoresist composition.

By way of summation and review, on the spin coating-finished wafer, an edge bead (generated by concentration and curing of the coating film on an edge of the wafer due to centrifugal force caused by the rotation of the wafer and interaction of surface tension) may be present. Such an edge bead on the wafer could cause a defect in a subsequent process, such as refracting light during light exposure to form a pattern on the wafer, or generating particles due to contact with a cassette when the wafer is drawn in or out a wafer storage cassette.

One or more embodiments may provide a manufacturing apparatus for a semiconductor device that uses a rotating wafer.

One or more embodiments may provide a manufacturing apparatus for a semiconductor device that may help reduce or prevent a defect of a manufactured semiconductor device by calibrating a variation of a displacement of a lateral surface of a rotating wafer, and spraying a chemical.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A manufacturing apparatus for a semiconductor device, the manufacturing apparatus comprising:
a spin chuck configured to fix and rotate a wafer;
a nozzle configured to spray a chemical toward the wafer;
a lateral displacement sensor configured to measure a displacement variation to a lateral surface of the wafer while the spin chuck is being rotated; and
a controller configured to control a position of the nozzle by using the displacement variation while the spin chuck is being rotated.

2. The manufacturing apparatus as claimed in claim 1, wherein the lateral displacement sensor includes a laser displacement sensor.

3. The manufacturing apparatus as claimed in claim 1, wherein the lateral displacement sensor is configured to measure the displacement variation to a predetermined measurement region, which is a part of the lateral surface of the wafer.

4. The manufacturing apparatus as claimed in claim 3, wherein, when the predetermined measurement region is positioned below the nozzle as the wafer is rotated, the controller is configured to move the position of the nozzle as much as the displacement variation.

5. The manufacturing apparatus as claimed in claim 1, wherein the controller is configured to learn the displacement variation with respect to a time, and to control the position of the nozzle with respect to the time by using the learned displacement variation.

6. The manufacturing apparatus as claimed in claim 5, wherein the controller is configured to measure the displacement variations during a plurality of periods, to average the displacement variations regarding the respective periods, and to learn the displacement variation with respect to the time.

7. The manufacturing apparatus as claimed in claim 1, wherein:
the spin chuck includes a magnetic levitation spindle motor, and
the controller is configured to control a position of the wafer by controlling the magnetic levitation spindle motor.

8. The manufacturing apparatus as claimed in claim 7, wherein the controller is configured to make a rotation axis of the wafer and a center axis of the wafer coincide with each other by using the displacement variation.

9. The manufacturing apparatus as claimed in claim 1, wherein:
the lateral displacement sensor is configured to further measure a height variation of the lateral surface of the wafer while the wafer is being rotated, and
the controller is configured to control the position of the nozzle by using the displacement variation and the height variation.

10. A manufacturing apparatus for a semiconductor device, the manufacturing apparatus comprising:
a spin chuck configured to fix and rotate a wafer;
a nozzle configured to spray a chemical toward the wafer;
a robot arm configured to fix the nozzle and to be driven in a horizontal direction and a vertical direction with respect to a top surface of the wafer; and
a lateral displacement sensor configured to measure a displacement variation to a lateral surface of the wafer and a height variation of the lateral surface of the wafer while the spin chuck is being rotated,
wherein the robot arm is configured to control a position of the nozzle to correspond to the displacement variation and the height variation, which are measured by the lateral displacement sensor.

11. The manufacturing apparatus as claimed in claim 10, wherein the nozzle moves, drawing a Lissajous curve on a plane comprising the horizontal direction and the vertical direction.

12. The manufacturing apparatus as claimed in claim 10, wherein the robot arm is configured to control the position of the nozzle in order for the nozzle to spray the chemical toward an edge of the wafer.

13. The manufacturing apparatus as claimed in claim 12, wherein:
the wafer includes a coating film coated over a top surface thereof, and
the robot arm is configured to control the position of the nozzle in order for the nozzle to remove an edge bead of the coating film.

14. The manufacturing apparatus as claimed in claim 12, wherein:
the wafer includes a coating film coated over a rear surface thereof, and
the robot arm is configured to control the position of the nozzle in order for the nozzle to spray the chemical toward the rear surface of the wafer.

15. The manufacturing apparatus as claimed in claim 12, wherein the chemical includes a rinse liquid.

16. The manufacturing apparatus as claimed in claim 10, wherein the robot arm is configured to control the position of the nozzle in order for the nozzle to spray the chemical toward a center axis of the wafer.

17. The manufacturing apparatus as claimed in claim 16, wherein the chemical includes a photoresist composition.

18. A manufacturing apparatus for a semiconductor device, the manufacturing apparatus comprising:
a spin chuck configured to fix and rotate a wafer having a photoresist thereon;
a nozzle configured to spray a rinse liquid toward the photoresist on an edge of the wafer;
a robot arm configured to fix the nozzle and to be driven in a horizontal direction with respect to a top surface of the wafer; and
a lateral displacement sensor configured to measure a displacement variation to a lateral surface of the wafer while the spin chuck is being rotated,
wherein the robot arm is configured to control a position of the nozzle to correspond to the displacement variation which is measured by the lateral displacement sensor.

19. The manufacturing apparatus as claimed in claim 18, wherein:
the robot arm is configured to be further driven in a vertical direction with respect to the top surface of the wafer,
the lateral displacement sensor is configured to further measure a height variation of the lateral surface of the wafer while the wafer is being rotated, and
the robot arm is configured to control the position of the nozzle to correspond to the displacement variation and the height variation.

20. The manufacturing apparatus as claimed in claim 18, wherein:
the spin chuck includes a magnetic levitation spindle motor, and
the magnetic levitation spindle motor is configured to make a rotation axis of the wafer and a center axis of the wafer coincide with each other by using the displacement variation.
